(19) United States
(12) Patent Application Publication
(10) Pub. No.: US 2017/0315183 A1
(43) Pub. Date: Nov. 2, 2017

(54) Battery pack tester and connected app for bluetooth connected smart device

(71) Applicant: Global Technology Systems, Inc., Framingham, MA (US)

(72) Inventors: Chien-Chih Chao, West Palm Beach, FL (US); Danny Rockett, Gainesville, GA (US); Lawrence A. Murray, Framingham, MA (US)

(21) Appl. No.: 15/581,955

(22) Filed: Apr. 28, 2017

Related U.S. Application Data
(60) Provisional application No. 62/329,506, filed on Apr. 29, 2016.

(51) Int. Cl. G01R 31/36

(52) U.S. Cl. CPC G01R 31/3679; G01R 31/3648

(57) ABSTRACT

Disclosed is a system for managing and replacing batteries. In particular, a rapid field tester that pairs via Bluetooth with a smart device, such as a mobile phone. The smart device containing an APP that further interfaces with a remote server to provide management of the battery. A user can test their battery and receive a visual indication if the battery passes or fails predetermined conditions. If the battery fails the test, a replacement battery will be automatically sent to the user. All of the test data is logged through the server and provided to the user in order to facilitate effective battery management.

### CROSS REFERENCE TO RELATED APPLICATION

In accordance with 37 C.F.R. 1.76, a claim of priority is included in an Application Data Sheet filed concurrently herewith. Accordingly, the present invention claims priority to U.S. Provisional Patent Application No. 62/329,506, filed Apr. 29, 2016, entitled “Battery Pack Tester and Connected APP for Bluetooth Connected Smart Device”, the contents of which is incorporated herein by reference.

### FIELD OF THE INVENTION

This invention is related to the battery field and in particular to a system for testing, managing and replacing batteries used in mobile devices.

### BACKGROUND OF THE INVENTION

Electrochemical power sources have had significant improvements in design, economy, and operating range and will play a vital role in the future in automobiles, power storage, military, mobile-station, and space applications.

Lithium chemistry based batteries, commonly referred to as Li-ion, are becoming increasingly popular for energy storage in portable electronic devices. Compared to alternative battery technologies, Li-ion batteries provide one of the best energy-to-weight ratios, exhibit no memory effect, and experience low self-discharge when not in use. These beneficial properties, as well as decreased costs, have established Li-ion batteries as the leading choice to power most mobile devices.

However, large scale users of portable devices, such as retailers, transportation, logistics, public safety, have not been able to quickly and efficiently test the rechargeable Li-ion battery packs or battery packs using other chemistries used in portable devices in order to determine their state of health.

For instance, bad batteries (high impedance) will charge up faster than good ones because their high impedance prevents them from taking on a full charge. So workers generally take the first “fully charged” battery from the charger and they find that it quits after a short time. This is important because using old batteries can cause unanticipated mid-shift failures of the device, and in critical applications, put lives and property at risk.

Until now, it has been necessary to test batteries using fixed location testers that put the battery pack through repeated charge-recharge cycles. This process generally takes hours or days for each battery pack tested. An alternative is to observe multiple failures of the battery pack during normal use and be able to correlate the time when the failure occurred since it was fully charged. When many batteries are used or when batteries are used in remote locations such as delivery routes, these processes become impractical. As a result, portable device users generally let the old batteries accumulate and circulate along with the newer ones. This results in inconsistent operations and inefficiencies and potential losses of property and life.

Using conventional methods to identify and remove old batteries from circulation is difficult and time-consuming, and generally not practical in a dynamic environment. When new battery packs are purchased there is no plan or process to efficiently remove the old ones. The result is that over time, a mixed population of good and bad batteries builds up in the enterprise, with no practical way to separate them and remove the bad ones. This situation often builds to a point where some companies will dispose of all batteries, good and bad, in order to clean up the work area, eliminate confusion and start over with all new batteries.

Thus, what is needed in the art is a battery pack tester and connected APP for a bluetooth connected smart device for managing and replacing batteries used in mobile devices.

### SUMMARY OF THE INVENTION

Disclosed is a system for managing and replacing batteries used in mobile devices. In particular, a rapid field tester that pairs via Bluetooth with a mobile phone APP. The device user can test their battery and visually see the pass/fail result on the APP.

A collective database is employed for storage of tested values; by customer, location, company battery type, battery condition, battery replacement schedule, battery disposal record.

Storage of data locally for uploading at available time and place; system provides complete portability of battery analysis without being directly tied to database. The database allows automatic order entry for replacement of failed packs with new ones, directly ordered upon completion of testing.

The database provides record keeping of pass and failed units, useful for upper management review of fleet performance and replacement/budgetary purposes.

The system is portable and consists of the battery tester, smart device app, an on-line database service. The tester is configurable to variety of battery packs to provide on-the-spot battery health without cycling of the battery pack through charge and discharge.

User data is provided stating whether the battery should be replaced and if a higher performing product should be used. All test data is logged and provided to the device user in order to facilitate effective battery management going forward.

An objective of the invention is to provide a quick, economical on-site portable testing of battery packs.

Another objective of the invention is to teach a technique for determining a battery's state of health as opposed to the conventional technique used to determine a battery's state of charge.

Still another objective of the invention is to disclose a method of testing, having an acceptable degree of accuracy, a battery pack in a dynamic environment while the battery is in service if it is ready to fail.

Still another objective of the invention is to disclose a method of testing a battery pack to predict failures thereby cutting the operational costs of mobile devices use in retail, warehousing and logistics.

Yet still another objective of the invention is to disclose a method of testing a battery pack that allows customers to quickly and easily identify old battery packs with a predicted time span so that a new battery pack is timely replaced.

Another objective of the invention is to provide a data base and report generator that: accumulates and processes the data extracted from each battery pack; provides a list of the “bad” batteries that are to be removed from the workplace; provides an inventory of all mobile battery packs in the enterprise; enables the user to sort and manage a large population of battery packs; provides for automated direct reordering of replacement battery backs; records the disposal of bad packs; develops a pattern of battery pack usage.

Yet still another objective of the invention is to reduce the amount of batteries that needs to be purchased; reduce inventories; systematically reduce old high impedance batteries from the work area; reduce service contact costs; reduce device downtime and work stoppages; and reduce the costs of battery disposal.

Another objective of the invention is to eliminate the need for a customer to coordinate and order replacement batteries wherein the disclosed APP may be used to automatically order a replacement battery should a tester indicate a battery pack in a failure mode. The customers quickly receive replacement batteries when they are needed, at the facility where they are needed, eliminating guessing and inventory burdens.

Still another objective of the invention is to provide a tester that adapts quickly between device/battery models from different manufacturers.

Another objective of the invention is to have the data collected, processed, transmitted and stored outside of a customer's in-house fire wall to avoid the complexity of dealing with data security systems that are designed for such things as financial information such as credit card data rather than non-secure battery conditions and inventory or other repair information.

An advantage of the invention is to identify and remove high-impedance batteries as they age to prevent equipment failure. While all batteries look alike, the older batteries that develop high-impedance will charge up fast and appear to be good. However, high-impedance batteries last for shorter and shorter periods, causing mid-shift failures and serious productivity loss. In addition, the fast-charging bad batteries pile up and cause false “failures” of the devices themselves—bad batteries are responsible for about 30% of device repairs.

Other objectives and further advantages and benefits associated with this invention will be apparent to those skilled in the art from the description, examples and claims which follow.

### BRIEF DESCRIPTION OF THE DRAWINGS

FIG. 1 is a login screen shot of the disclosed APP;

FIG. 2 is a battery selector screen shot of the APP;

FIG. 3 is a ready to test screen shot of the APP;

FIG. 4 is a pictorial of the battery tester;

FIG. 5 is a failure screen shot of the APP;

FIG. 6 is a pass/fail screen shot of the APP;

FIG. 7 is an order management flow diagram of the system;

FIG. 8 is a flow diagram of the programmable load circuit.

### DETAILED DESCRIPTION OF THE PREFERRED EMBODIMENT

Disclosed is a device and method of testing a battery pack in a dynamic state to determine when the battery pack is about to fail. The end user or customer can perform testing by themselves during normal maintenance routines providing an easy way of identifying battery packs that are ready for replacement.

The device and method incorporates a proprietary APP for smart devices such as the iPhone or Android telephones, and the like smart devices. This APP allows the smart device to work in combination with a tester device using testing protocols and algorithms for each model of a battery pack to determine battery condition. The smart device also serves as the conduit for collecting the test information and sending it to a server. The smart phone APP connects to an on-line database which is used to stored and manage the test data and provide reports to the owner of the battery being tested. Further, a process within the APP and server can automatically order a new battery pack when a bad pack is identified.

The tester and smart device operates inside a customer's facilities to gather data on the battery operation including testing activity, recycling, and purchasing functions, in real time. The tester is connected to the smart device using the APP, via Blue-tooth or other wireless means, which is connected via wi-fi or other means to a remote server. The smart device has multiple capabilities including receiving and storing data from the tester. In addition to testing the battery, the smart device can be used to read bar-codes, take and receive photos or video of the battery and transmit them to the server. The resulting information using certain analytics is returned to the battery owner/customer in the form of management reports. Further, the customer can gather their own data using the tester and APP.

The tester is constructed and arranged to look into the battery cell directly. Using small probes, a small known electrical load of voltage and current is put onto the battery terminals for a few seconds. When the load is removed, the rebound or deformation of the voltage bounce back is measured. The bounce back response has a direct correlation to capacity loss. Predicted values for each battery pack model are predetermined and the algorithms process the data and convert it into a quick pass/fail indication. The limits of the pass/fail indicator can be adjusted depending on the way the battery is used (i.e. more strict for public safety, more relaxed for a warehouse).

For example, old, bad battery packs can cause a major problem in the mobile Enterprise since most companies do not have an economical and effective way to deal with aging batteries, resulting in wasted time and money. Each mobile device may have multiple spare batteries, some old and some new wherein a medium size business may have an investment of several million dollars in battery packs alone.

The system includes a miniaturized battery pack tester for use with a smart device, such as a smartphone. The smartphone would include an APP that couples to an on-line service containing a database for managing the batteries. The battery tester and Smartphone APP enable customers to use their own Smartphones to periodically test all of their mobile device battery packs. In a few seconds they can identify and mark the bad ones to be replaced. As each battery is tested, the APP compiles a list of these bad batteries and sends it to the on-line Server. This data is compiled, and replacement batteries are automatically sent to that location to replace the batteries that fail testing, as determined by the database records. The Server can send a report to the customer with details of the testing results and the replacement batteries that are sent to each location.

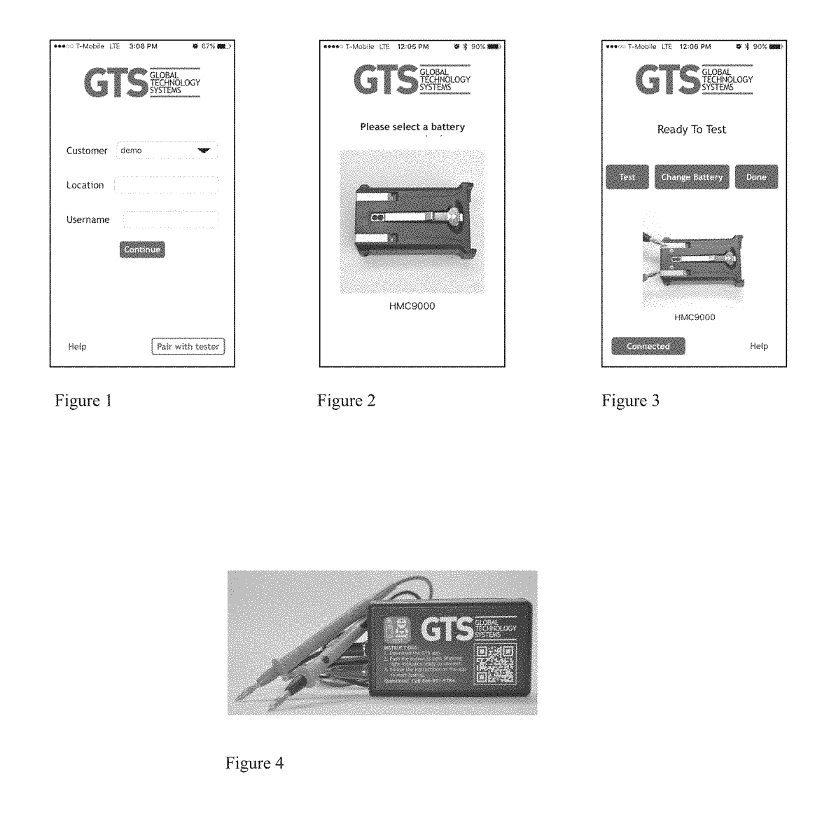

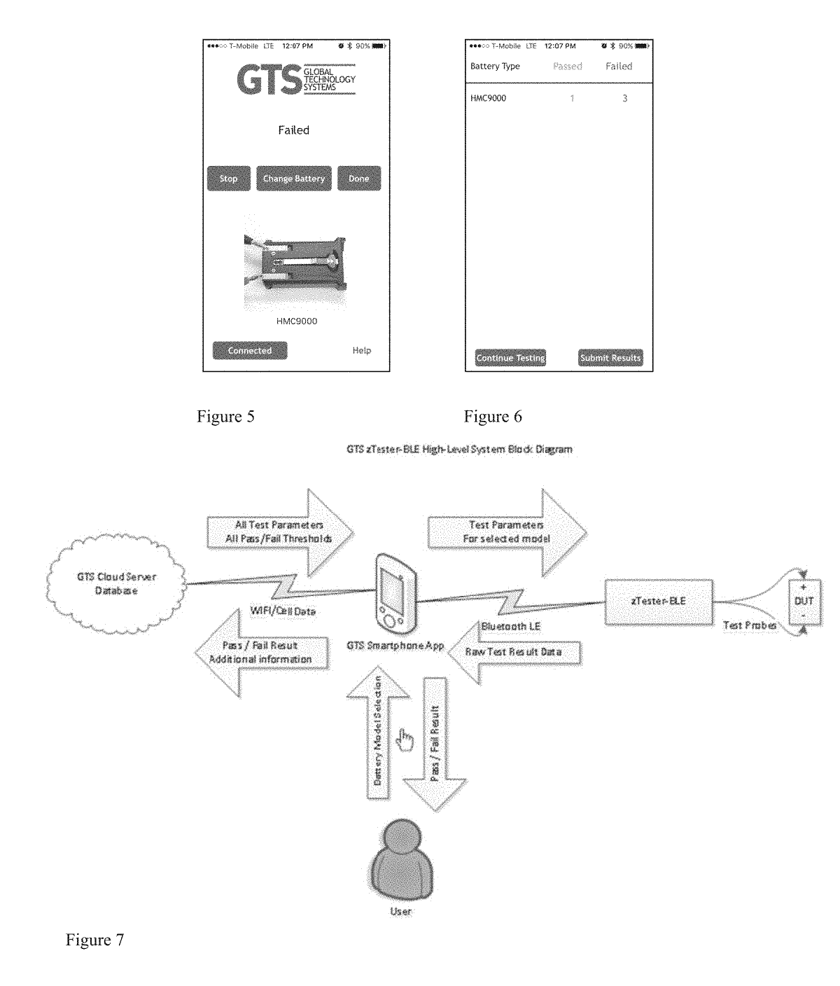

Currently, device users have no means of knowing the state of health of their batteries. Batteries that have exceeded their useful life stay in circulation driving maintenance costs and work stoppages. The process flow is as follows:
1. A unique customer account is created on a server. The test protocol and pass/fail criteria for each battery are housed within this profile.
2. The user downloads an APP and pairs their smart device, such as a smartphone, with the Bluetooth enabled tester.
3. The user logs into their account via the mobile phone application, FIG. 1. When the user logs in, the customer profile is pulled from the server.
4. The user is then shown a list of batteries within their profile FIG. 2. When they select the battery that they wish to test, they are taken to the test screen FIG. 3.
5. The user then probes the contacts of the battery that they are testing using the tester (FIG. 4). The test takes approximately 5 seconds, and then a pass/fail result is displayed (FIG. 5).
6. The user is able to see the cumulative results of their testing session by selecting “done” on the APP (FIG. 6). The results are sent to the Server when the user selects “submit results”
7. The Service instructs and automatically sends a replacement battery, for every battery that fails, to the exact location where the failure was recorded.

The Tester device has two attached probes that when touched to the battery's contacts, will extract State of Health (SOH) data from a battery pack. This is done on site, requires no special training or expertise, and can be completed in less than 5 seconds.

The data base and report generator on the Service:
accumulates and processes the data extracted from each battery pack;
provides a list of the “bad” batteries that are to be removed from the workplace;
provides an inventory of all mobile battery packs in the enterprise;
enables the user to sort and manage a large population of battery packs;
provides for automated direct reordering of replacement battery backs;
records the disposal of bad packs; and
develops a pattern of battery pack usage.

The Tester (50) is connected to the APP (52) via Bluetooth (54) to the smart device. When a battery (100) is tested, the extracted state of health (SOH) data is kept for either immediate transfer to the database (56) or later when Wi-Fi (58) is available. Once downloaded, it becomes part of an enterprise-wide database for budgeting, purchasing, and performance management.

The Tester is portable, hand held, self-contained, and requires no external power. The Tester uses a “battery z” technique to analyze the battery at a chemical level to determine its current state of health. In this technique, the system determines the “State of Health” of a battery pack which is very different from state of charge. For example, a battery could show 100% state of charge but might only last for an hour or two because it has a poor state of health.

Detecting of bad batteries is accomplished through monitoring and analysis of the process of electrochemical polarization wherein certain mechanical side-effects of the battery's electrochemical activity cause isolating barriers to develop at the interface between electrode and electrolyte. These side-effects influence the reaction mechanisms, as well as the chemical kinetics of corrosion and metal deposition.

The testing process requires the user to download the APP to a smart phone or other Bluetooth connected smart device. The APP permits the user to test only the battery packs located at an approved test location, unauthorized battery packs cannot be tested. The Tester and APP are paired with assistance from on-screen prompts. When paired, the system is now ready to test a battery pack using its Tester, APP and smart device. The smart device brings up the pre-installed menu of authorized battery models for testing and the user selects the pack model to be tested. The APP sends information to the Tester via Bluetooth and the Tester selects the appropriate pre-installed test protocol for that particular model. The Tester is now “programmed” to analyze the battery. The user places the Tester's two probes onto the pack terminals (Testing cannot occur if polarity is reversed). Data obtained by the Tester is sent to the smart device where it is evaluated and determined if the battery is good (pass indicator) or bad (failure indicator).

The test data is sent from the APP to the database, either at the time of the test or when Wi-Fi is available for upload. The user can “mark” the tested battery as good or bad (based on the data sent to smart phone) as the test results are displayed on the screen. This allows the user to remove bad batteries at the time of testing.

In the preferred embodiment, the tester is automatically paired with smart phone or other smart Bluetooth device. The Tester is automatically “programmed' to exacting set of test values for the specific battery, chemistry, configuration based on user identified battery model.

The smart device acts as master controller for the Tester by transmitting specific test values; test protocol with current and voltage ranges; final SOH test results; control of specific battery models analyzed by customer, user or location of test.

The test protocols for battery pack, chemistry, configuration, voltages all reside within the App; there is no need to have reference tables, instructional booklets or other means of programming the Tester.

A collective database is employed for storage of tested values; by customer, location, company battery type, battery condition, battery replacement schedule, battery disposal record. Storage of data locally for uploading at available time and place; system provides complete portability of battery analysis without being directly tied to database. The database allows automatic order entry for replacement of failed packs with new ones, directly ordered upon completion of testing. The database provides record keeping of pass and failed units, useful for upper management review of fleet performance and replacement/budgetary purposes.

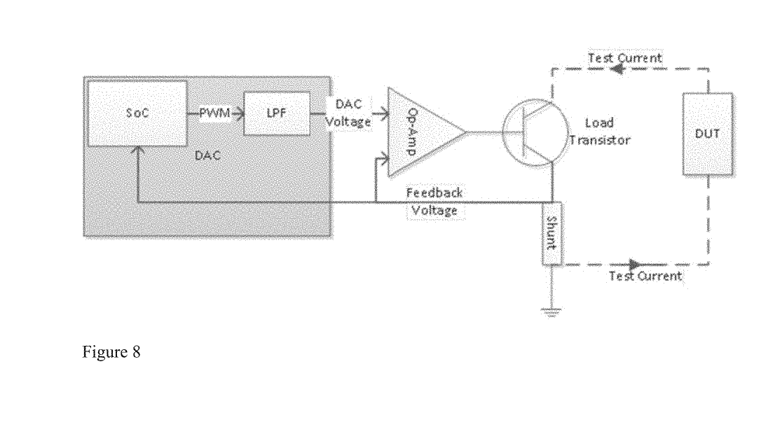

FIG. 8 depicts the programmable load circuit designed to draw a Test Current from the Device-Under-Test (DUT). The Test Current level (in Amps) can be selected within a range based on the parameters of the specific test required by the battery model. It consists of a Digital-to-Analog-Converter (DAC), an Op-Amp, a Load Transistor, and a Shunt. The System-on-Chip (SoC) outputs a Pulse-Width-Modulated (PWM) signal with a duty cycle which is an analog of the desired Test Current. The Low-Pass-Filter (LPF) converts the PWM signal to an analog DAC Voltage. The Op-Amp drives the Load Transistor such that the Feedback Voltage generated by the Test Current across the Shunt equals the DAC Voltage.

The system is a completely portable battery analyzer, app, and database that is easily configurable to variety of battery packs and chemistries. The system offers complete on-the-spot battery health (SOH) without undue cycling of packs through charge and discharge. The system provides user data to determine if battery should be replaced and if so, should a battery be immediately called from the fleet and replaced with higher performing products. The database and on-line service can be customized to address numerous types of proper data support and re-order scenarios.

It is to be understood that while a certain form of the invention is illustrated, it is not to be limited to the specific form or arrangement herein described and shown. It will be apparent to those skilled in the art that various changes may be made without departing from the scope of the invention and the invention is not to be considered limited to what is shown and described in the specification and any drawings/figures included herein.

One skilled in the art will readily appreciate that the present invention is well adapted to carry out the objectives and obtain the ends and advantages mentioned, as well as those inherent therein. The embodiments, methods, procedures and techniques described herein are presently representative of the preferred embodiments, are intended to be exemplary and are not intended as limitations on the scope. Changes therein and other uses will occur to those skilled in the art which are encompassed within the spirit of the invention and are defined by the scope of the appended claims. Although the invention has been described in connection with specific preferred embodiments, it should be understood that the invention as claimed should not be unduly limited to such specific embodiments. Indeed, various modifications of the described modes for carrying out the invention which are obvious to those skilled in the art are intended to be within the scope of the following claims.

What is claimed is:

1. A method of testing a battery state of health comprising the steps of:
measuring a battery isolating barriers that develop at the interface between an electrode and electrolyte by a tester coupled to a smart device;
checking said battery isolating barriers against predicted values for said battery;
indicating on said smart device if said battery is outside said predicted values.

2. The method of testing a battery state of health according to claim 1 wherein smart device indicates a pass condition if within said predicted values or a fail condition if outside said predicted values.

3. The method of testing a battery state of health according to claim 1 wherein said predicted values are adjustable to accommodate battery usage and user operating patterns.

4. The method of testing a battery state of health according to claim 1 including the steps of:
establishing a base level of electrochemical polarization caused by the isolating barriers;
repeat testing of said battery isolating barriers to detect changes from said base level;
displaying a pass/fail condition on the smart device;
replacing said battery upon notice of a fail condition;
wherein said battery is tested, managing and replaced before total failure.

5. The method of testing a battery according to claim 1 wherein said battery isolating barrier is a measurement of the chemical kinetics of corrosion and metal deposition within the battery.

6. The method of testing a battery according to claim 1 wherein said battery is lithium chemistry based.

7. The method of testing a battery state of health according to claim 1 wherein the step of measuring battery isolating barriers is performed by: placing a temporary known load of voltage and current on the battery terminals and measuring the deformation of voltage bounce back.

8. The method of testing a battery according to claim 1 wherein said step of measuring comprising the steps of:
installing an APP on a smart device, said APP programmed with a database to record battery testing levels;
pairing said smart device with said tester;
selecting a battery model to be tested;
touching probes of said battery with said tester;
sending data collected by said tester to a remote database, said database having preprogrammed levels to determine if the battery is in a failure mode;
reporting battery condition.

9. The method of testing a battery according to claim 2 including the step of automatically sending replacement batteries upon a failure condition.

10. The method of testing a battery according to claim 2 wherein said step of measuring includes a tester having an op-amp that drives a load transistor wherein a feedback voltage is generated, measured and compared across a shunt.
